(19) United States
(12) Patent Application Publication
(10) Pub. No.: US 2008/0315430 A1
(43) Pub. Date: Dec. 25, 2008

(54) NANOWIRE VIAS

(75) Inventors: WALTER M. WEBER, Munich (DE); Franz Kreupl, Munich (DE); Eugen Unger, Augsburg (DE)

Correspondence Address: DICKSTEIN SHAPIRO, LLP, 1177 AVENUE OF THE AMERICAS, NEW YORK, NY, 10036-2714, US

(73) Assignee: QIMONDA AG, Munich (DE)

(21) Appl. No.: 11/767,066

(22) Filed: Jun. 22, 2007

(51) Int. Cl. H01L 29/40; H01L 21/768

(52) U.S. Cl. 257/774; 438/667; 438/393; 257/E21.597; 257/E25.001

(57) ABSTRACT

A method of fabricating an integrated circuit including arranging a nanowire with a first end portion thereof at a first contact surface of a first electrical contact and with a second end portion sticking up from the first contact surface, and embedding at least part of the nanowire in dielectric material.

### TECHNICAL FIELD

This description is directed to an interconnection in an integrated circuit and a method of fabricating an interconnection in an integrated circuit.

Details of one or more implementations are set forth in the accompanying exemplary drawings and exemplary description below. Other features will be apparent from the description and drawings, and from the claims.

### BRIEF DESCRIPTION OF THE DRAWINGS

FIG. 1 shows an example of an integrated circuit;

FIGS. 2A to 2K demonstrate a first example of fabricating an integrated circuit comprising an electrical interconnection;

FIGS. 3A to 3F show another example of fabricating an integrated circuit;

FIGS. 4A to 4N show yet another example of fabrication an electrical interconnection in an integrated circuit; and

FIGS. 5A to 5D show another example of fabricating an integrated circuit comprising a capacitor structure; and

FIGS. 6 and 7 show microscopic pictures demonstrating a fabrication of nanowires.

### DETAILED DESCRIPTION

An integrated circuit may, for example, comprise two or more levels of circuit layers and/or wiring layers. One of the circuit layers may, for example comprise an active semiconductor layer or semiconductor operation layer comprising transistor elements, for example. A wiring layer may, for example, comprise a structured metallization layer providing lateral interconnections. The integrated circuit may further comprise vertical interconnection elements, such as electrically conductive vias, for example, that may provide electrical interconnection between different, and particularly neighboring or adjacent circuit layers.

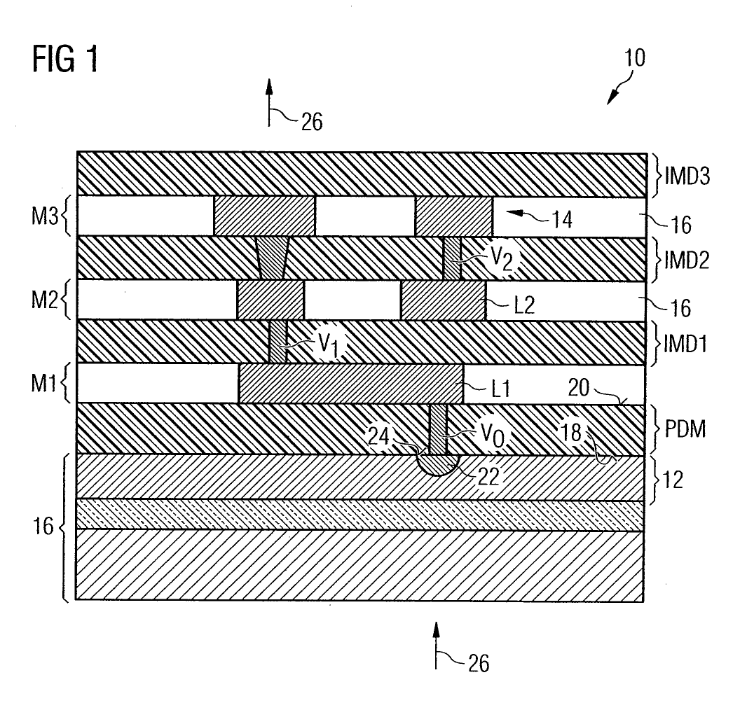

FIG. 1 shows a schematic cross sectional view of an exemplary integrated circuit 10. In one aspect, this integrated circuit may comprise one or more structured metallization layers, such as a first-level metallization layer M1, a second-level metallization layer M2, etc. Nevertheless, the integrated circuit is not limited to a plurality of metallization layers. In one example, only one metallization layer M1 may be provided. The metallization layers may be structured such that they may comprise one or more laterally extending conduction lines or interconnection lines L1, L2, etc., which may be arranged in trenches 14 formed in insulating material, such as a dielectric trench isolation material 16 exemplarily shown in FIG. 1. The dielectric trench isolation material 16 may be comprised in the structured metallization layers M1, M2, etc. and may be formed as dielectric trench isolation layers 16 when forming the metallization layers, for example.

In one aspect, such as in the example shown in FIG. 1, an integrated circuit may comprise a semiconductor operation layer 12 with a substrate surface or operation layer surface 18. In one aspect, during fabrication of the integrated circuit, the operation layer surface may represent a first process surface. At least part of the operation layer surface 18 may be planar. The semiconductor operation layer 12 may comprise one or more electrically conductive operation layer contact regions 22, such as a source contact or a drain contact or a gate contact of a transistor structure, for example. The operation layer contact region 22 may comprise doped semiconductor material, for example. In another example, the operation layer contact region 22 may comprise metal material. A contact surface 24 of the operation layer contact region 22 may form at least part of the operation layer surface 18.

In one example, a pre-metal dielectric layer PMD is arranged at the operation layer surface 18 (or substrate surface) and it may at least partly separate the structured first-level metallization layer M1 from the semiconductor operation layer 12. An upper surface 20 of the pre-metal dielectric layer PMD, which, in one aspect, may be referred to as a second process surface during fabrication of an integrated circuit, may be planar, for example. In another example, only part of the upper surface 20 of the pre-metal dielectric layer PMD is planar. Nevertheless, the integrated circuit 10 is not limited to planar surfaces. The first-level metallization layer M1 may be arranged at the upper surface 20 of the pre-metal dielectric layer PMD being thereby at least partly separated physically from the operation layer surface 18. Moreover, the pre-metal dielectric layer PMD may at least partly electrically isolate the first-lever metallization layer M1, particularly at least some of the interconnection lines L1 formed therein, from the semiconductor operation layer 12, while in one aspect at least one of the interconnection lines L1 may be electrically interconnected locally to the operation layer contact region 22 through a via conductor V₀ formed in the pre-metal dielectric layer PMD.

In case the integrated circuit 10 comprises more than one structured metallization layers M1, M2, etc., neighboring or adjacent levels of structured metallization layers M1, M2, etc. may be at least partly separated by inter-metal dielectric layers IMD1, IMD1, as exemplarily shown in FIG. 1. Accordingly, the structured metallization layers may be at least partly separated physically by the inter-metal dielectric layers IMD1, IMD2, etc. Moreover, they may be at least partly separated or isolated electrically by the inter-metal dielectric layers IMD1, IMD, etc., while neighboring levels of structured metallization layers M1, M2, particularly at least some of the conduction lines or interconnection lines L1, L2, for example, may be electrically interconnected through via conductors V1, V2, etc. (also called vias) formed in the inter-metal dielectric layer therebetween.

The integrated circuit is not limited to planar and parallel layers as shown in FIG. 1. In more general, according to one aspect, an integrated circuit may comprise a first circuit layer and a second circuit layer separated from the first circuit layer by a dielectric layer, where a first contact region in the first circuit layer is electrically connected to a second contact region in the second circuit layer by a via conductor formed in the dielectric layer. The via conductors may comprise semiconductor nanowires.

In one aspect an integrated circuit may comprise a first circuit layer such as the semiconductor operation layer 12 or one of the metallization layers M1, M2, for example. This first circuit layer may comprise at least one first electrical contact such as the operation layer contact region 22 or the interconnection lines L1, L2, for example. The integrated circuit may further comprise a second circuit layer such as the metallization layer M1, M2, M3, for example. The second circuit layer may comprise at least one second electrical contact such as the interconnection lines L1, L2, for example. The second circuit layer, and particularly the second electrical contact may be separated from the first circuit layer, and particularly from the first electrical contact by a dielectric separation layer such as pre-metal dielectric layer PMD or an inter-metal dielectric layer IMD1, IMD2, for example. Furthermore, the integrated circuit may comprise a nanowire as a via conductor such as the via conductor V₀, V₁, V₂, for example. The nanowire may be arranged in the dielectric separation layer and may provide electrical conductance between the first electrical contact in the first circuit layer and the second electrical contact in the second circuit layer.

In one example the nanowire is a doped semiconductor nanowire. Any semiconductor material and any suitable doping may be applied for providing an electrically conductive via conductor. In another example the nanowire comprises metal atoms. Metal atoms may for example be diffused into a semiconductor nanowire to enhance the electrical conductance of the nanowire. In one example, the nanowire may be provided as a silicon nanowire and nickel may be diffused into the nanowire to form an electrically conductive nickel-silicide nanowire. In another example other semiconductor material or other metal may be applied. In yet another example, the nanowire may be grown as an electrically conductive doped semiconductor nanowire.

In one aspect, the first circuit layer comprises a semiconductor operation layer such as the operation layer 12 shown in FIG. 1, for example. In this case, the first electrical contact may comprise a source or drain contact of a transistor provided in the semiconductor operation layer. In another aspect, at least one of the first and second circuit layer comprises a structured metallization layer and at least one of the first and second electrical contact comprises a metal interconnection line.

In one exemplary integrated circuit, nanowires vias may form vertical conductors or interlayer connection and may be applied to provide signal connections and/or power connection, for example.

In one aspect, the nanowire comprises semiconductor material such as silicon, germanium, a group III-V-semiconductor, such as BN, BP, BAs, AlN, AlP, AlAs, AlSb, GaN, GaP, GaAs, GaSb, InN, InP, InAs, InSb, for example, or a group II-VI-semiconductor, such as ZnO, ZnS, ZnSe, ZnTe, CdS, CdSe, CdTe, HgS, HgSe, HgTe BeS, BeSe, BeTe, MgS, MgSe, for example, or one or more of the compounds GeS, GeSe, GeTe, SnS, SnSe, SnTe, PbO, PbS, PbSe, PbTe, CuF, CuCl, CuBr, CuI, AgF, AgCl, AgBr, AgI, for example.

In one aspect, the nanowire may be at least partly mono-crystalline, i.e. it may comprise a wire section that consists of a single crystal, where the mono-crystalline wire section has a length not smaller than the diameter of the nanowire or even not smaller than twice or even five times the nanowire diameter.

In particular, when reducing lateral structure size in an integrated circuit, i.e. the lateral extent of the via conductor, semiconductor nanowires still provide sufficiently high conductivity even when fabricated with a lateral extent of less than 100 nm or less than 50 nm or even less than 20 nm, for example. Moreover, in one aspect, a nanowire via may be fabricated with a lateral extent of less than 50 nm or even less than 20 nm without requiring optical lithography with the same high special resolution. In one aspect the at least one nanowire via or nanowire interlayer connection may be provided with a high aspect ratio, such as at least 5, or at least 10, or even up to 200 or more, for example.

In one aspect the integrated circuit 10 may have a substrate normal direction 26 as exemplarily indicated in FIG. 1. Directions parallel to the substrate normal direction 26 may be referred to as “vertical”, while directions perpendicular to the substrate normal direction 24 may be referred to as “horizontal” or “lateral” throughout this description. In this sense the semiconductor operation layer 12 and/or the pre-metal dielectric layer PMD and/or at least one of the inter-metal dielectric layers IMD1, IMD2, etc. and/or at least one of the structured metallization layers M1, M2, etc. may extend at least partly in substantially horizontal direction, for example, i.e. in one aspect they may be substantially parallel to each other and to the horizontal directions. In one example the interlayer connections or via conductors V₀, V₁, V₂, on the other hand, may at least partly extend in a direction having a vertical component. In particular, nanowire vias may have a longitudinal extent that is at least partly oriented in a substantially vertical direction.

In another aspect, described in more detail below, an integrated circuit may comprise a first electrical contact arranged in a first circuit layer and having a first contact surface. In this example the integrated circuit may further comprise at least one electrically conductive nanowire arranged with a first end portion thereof at the first contact surface and with a second end portion sticking up from the first contact surface. Moreover, the integrated circuit may further comprise a capacitor counter electrode separated from the at least one electrically conductive nanowire by a capacitor dielectric layer. In one example, a major portion of the nanowire is embedded in the capacitor dielectric layer. In a further example, the first circuit layer comprises a select transistor of a memory cell and wherein the first electrical contact comprises a source or drain contact of the select transistor. Accordingly, the nanowire may be applied for a capacitor of memory device, such as a DRAM or a non-volatile memory device, for example. In another example, the first electrical contact is provided as a gate contact of a field effect transistor such as the select transistor, for example, and the second electrical contact may be provided as a word line.

In one aspect, an integrated circuit may comprise a combination of different active and/or passive components, such as memories and/or processing units and/or input/output interfaces, for example. In one aspect, a device may comprise at least one resistive memory cell that may be based on a substantially vertical nanowire arranged with one end portion thereof at an electrical contact, for example. In one example, an integrated circuit may comprise a DRAM, particularly a stack-cell DRAM, or any non-volatile memory component.

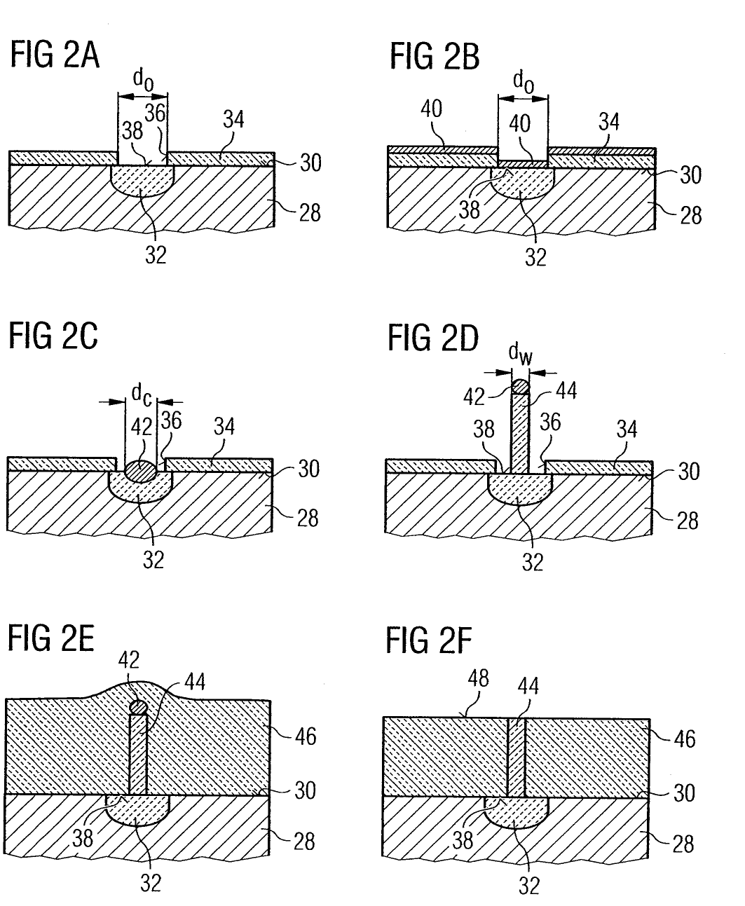

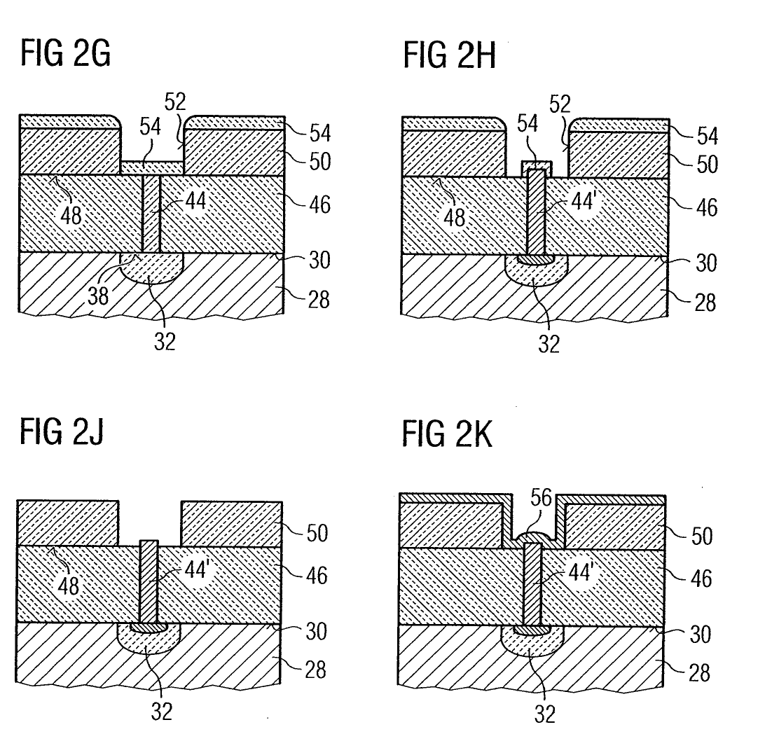

In a further aspect, descried in more detail in connection with FIGS. 2 to 5, a method of fabricating an integrated circuit may comprise arranging a nanowire such as a semiconductor nanowire with a first end portion thereof at a first contact surface of a first electrical contact and with a second end portion sticking up from the first contact surface; and embedding at least part of the nanowire in dielectric material. The first contact surface may be part of a first process surface. In one example the first process surface may be an at least partly planar surface. The nanowire may be arranged with its second end portion sticking up from the first process surface.

In a further aspect, a method of fabricating an electrical interlayer connection in an integrated circuit may comprise providing a first circuit layer with a first process surface, the first circuit layer comprising a first electrical contact. The method may further comprise arranging an electrically conductive nanowire with a first end portion thereof at the first electrical contact and with a second end portion sticking up from the process surface. Furthermore, the method may comprise embedding the nanowire in a dielectric separation layer arranged at the first process surface and comprising a second process surface at least partly separated from the first process surface such that the nanowire extends through the dielectric separation layer from the first process surface to the second process surface. Moreover, the method may comprise arranging a second electrical contact at the second process surface such that it electrically connects the nanowire.

In one aspect, a method may provide a self-aligned formation of substantially vertical via interconnects or via conductors without the need of high resolution etching and filling contact holes to a first electrical contact such as a transistor contact after a deposition of a pre-metal dielectric layer or an inter-metal dielectric layer is performed. In particular, according to this aspect, a nanowire may be arranged at the first electrical contact as an at least partly free-standing nanowire, for example, before the deposition of a dielectric separation layer such as a pre-metal dielectric layer PMD or an inter-metal dielectric layer is performed.

In one aspect, nickel silicide nanowires may be implemented as vias. In one particular example, Si-nanowires are grown by CVD substantially vertically on the desired contact region such as a first electrical contact. The diameter of the nanowire may be smaller than 100 nm, for example. In one aspect the diameter of the nanowire is between about 5 nm and about 50 nm, more particularly between about 10 nm and about 20 nm.

According to one example, a semiconductor nanowire may be grown and metal atoms may be diffused into the nanowire afterwards. A metal reservoir, such as Ni, for example, may be formed either at a top or a bottom of the formed nanowire. In particular, the metal reservoir may be formed at a first or a second end portion of the nanowire. In one example, the metal reservoir may be formed on both the first and second end portion of the nanowire. In yet another example, at least one metal reservoir may be located at any part of the nanowire's surface, or it may even embed the nanowire's surface partially or completely. The metal reservoir may supply metal atoms, such as Ni, for example, as a diffusion species. Annealing may cause diffusion of metal atoms into the nanowire. Annealing may be performed at temperatures of about 280° C. In one example, diffusion occurs mainly in longitudinal direction along the nanowire from one end portion thereof towards the other end portion thereof. In particular, in case of a silicon nanowire this may cause a longitudinal silicidation of the nanowire, leading to a Ni-silicide nanowire, for example. Appropriate annealing conditions and a specific Ni content at the reservoir(s) will lead to a single-crystalline Ni-silicide nanowire formation, for example. In one aspect, there may be no or only few internal crystal boundaries inside the nanowire, so that no size effect will take place, i.e. a drastic decrease of the conductivity of the nanowire with a reduced nanowire diameter may be avoided.

In one example, resistivity of the nanowire via may be below 100 μΩcm, or even below 50 μΩcm or below 20 μΩcm. In one particular example, the resistivity of the nanowire via may be about 10 μΩcm with a nanowire diameter of about 29 nm. In one example, the nanowire, such as a Ni-silicide nanowire, may support a current density of more than 1×10⁷ A/cm² or even more than 5×10⁷ A/cm² or more than 1×10⁸ A/cm². In one particular example, the nanowire may support a current density of about 3×10⁸ A/cm². In another example a current density of even up to 1 GA/cm² may be supported, if heat can be dissipated rapidly.

In an exemplary integrated circuit, a via conductor for electrically connecting a transistors source contact to a bit-line, may be provided by epitaxially and substantially vertically growing a nanowire on a degenerately doped silicon region that forms the source contact. In one example fabrication of this via conductor is performed without etching a contact hole for the via conductor. For the upper via levels, Si nanowires may be grown out of lithographically defined holes on top of metallic layers such as the metallization layers M1, M2, M3 shown in FIG. 1, for example. High aspect ratios may be achieved for such via connections.

In one particular aspect, nickel silicide-nanowires are implemented as vias for interconnects, where the nanowires may be grown substantially perpendicular to a process surface for establishing vertical interconnects in a self-aligned manner, for example. To fabricate these via conductors, silicon nanowires may be grown at the desired position, then they are transformed to nickel silicide nanowires by the axial diffusion of Ni. Further, high aspect ratio vias can be fabricated from a nickel-silicide nanowire grown out of templates.

One particular example of an integrated circuit and a method of fabricating an integrated circuit is described in connection with FIG. 2 in the following. A self-aligned process for electrically connecting a transistor to a bit-line is exemplarily described. In one aspect, a nickel-silicide nanowire via may be applied for this purpose. This may result in a high integration density with relatively low lithographic effort.

As shown in FIG. 2A, a first circuit layer 28, such as the semiconductor active layer or semiconductor operation layer 12 described in connection with FIG. 1, for example, may be provided with a first process surface 30. The first circuit layer 28 may be provided as a structured or functionalized semiconductor substrate. Furthermore, a first electrical contact 32 may be provided as a doped semiconductor region that may form a source or a drain region of a field effect transistor, for example. In one example, the first electrical contact 32 may comprise a degenerately doped silicon (Si) region to be contacted. Nevertheless any other material, in particular any other semiconductor material or metallic material suitable for fabricating integrated circuits may be applied for the first electrical contact 32.

In the example shown in FIG. 2A, a lithographic hard mask 34 is created on the first process surface 30 of the first circuit layer 28. The lithographic hard mask 34 may act as a deposition mask for a subsequent deposition and structuring of a catalyst. Accordingly, a catalyst deposition window 36 is lithographically formed in the lithographic hard mask or catalyst deposition mask 34 to at least partly uncover a first contact surface 38 of the first electrical contact 32. In the example shown in FIG. 2A, the lithographic hard mask 34 with the catalyst deposition window 36 is formed before the creation of the first electrical contact 32. In particular the lithographic hard mask 34 is provided and applied also as an implantation mask 34 with an implantation window 36 for implantation doping of the semiconductor substrate 28. Afterwards the lithographic hard mask is reused for the subsequent catalyst deposition.

Although in the shown example the implantation window and the hard mask forming the same is used for further processing, the method is not limited to this. In another example, a separate hard mask or catalyst deposition mask for defining the first contact surface may be created after a removal of the implantation hard mask.

In one example the lithographic hard mask may comprise at least one material out of the group of materials comprising SiO₂ and Si₃N₄, for example. The characteristic size d₀ of the first electrical contact 32 or the first contact surface 38 is given by the used lithography and etching of the hard mask 34, for example.

As shown in FIG. 2B catalyst material is deposited as a catalyst layer 40 at least at the first contact surface. The catalyst layer 40 may be deposited with electron beam evaporation, for example. In one example, a gold layer (Au) is deposited as the catalyst layer 40. In another example, Ti, Al, Ni, Co, Mo, In, Ga, Pd or other metals or alloys may be applied for the catalyst layer 40. In another example, silicide forming material may be used. In one example, in particular when applying Au, the thickness of the catalyst layer 40 in substrate normal direction may be about 0.5 nm. The deposited catalyst does not need to form a closed layer. Depending on the thickness and wetting properties between the catalyst and a surface to which the catalyst is deposited, such as the first contact surface 38, for example, the catalyst layer 40 may be composed of clusters or islands in some examples.

Appropriate annealing of the catalyst layer 40 may let the catalyst material coalesce into small droplets forming at least one catalyst seed 42 at the first contact surface 38, as exemplarily shown in FIG. 2C. The position of the catalyst seed 42 on the first contact surface 38 will define the placement of a nanowire via to be formed. The position of the catalyst seed 42 at the first contact surface 38, therefore, may define an anchor region for the nanowire to be grown.

In one aspect, at least part of the catalyst material deposited on the first contact surface 38, i.e. located at the first electrical contact 32, forms silicide material, i.e. it exemplarily reacts with material from the first electrical contact 32. The unreacted catalyst material, such as the catalyst material deposited on the lithographic hard mask 34, may be etched away selectively to the silicide-particle of the catalyst seed 42 and the lithographic hard mask 34, as shown in FIG. 2C. For Au as catalyst material this can be done with aqua regia, for example. The remaining catalyst seed 42 may have a diameter d_{c} that is significantly smaller than the diameter d₀ of the lithographically formed catalyst deposition window 36 (d_{c}<<d₀). Accordingly, a diameter d_{w} of a nanowire 44 grown catalytically may be substantially smaller than lateral structure sizes of lithographic processes, since the diameter d_{w} of the nanowire 44 may be determined by the size of a coalesced catalyst seed 42 rather than by the lithographic size d₀ of the deposition window 36.

As shown in FIG. 2D, the nanowire 44, such as a Si-nanowire (NW) may be grown with a first end portion thereof arranged at the first contact surface and with a second end portion sticking up form the first contact surface 38 or the first process surface 30. The nanowire 44 is arranged at the previous location of the catalyst seed 42. The nanowire growth may be carried out using catalytic chemical vapor deposition (CVD), for example. In one example, silane (SiH₄) will be supplied while heating the sample, leading to the formation of the Si-nanowire 44 according to a vapor-liquid-solid (VLS) mechanism. In another example, nanowire wire growth may take place with a vapor-solid-solid growth mechanism. For Au as a catalyst, an exemplary temperature of about 320° C. may be applied. In one aspect, the applied temperature may be clearly below a pyrolitic decomposition temperature of SiH₄ (450-500° C.). Accordingly, in this aspect deposition of silicon on the sample apart from the nanowire growth, i.e. apart from the catalyst seed 42 can be reduced or even avoided.

In one example, the nanowire 44 may grow epitaxially and substantially perpendicular to the first contact surface 38 or the first process surface 30. Arranging the nanowire 44 at the first contact surface 38, therefore, may comprise epitaxially growing the nanowire as an at least partly free standing nanowire starting the growth from the first contact surface 38. The catalytical growth may particularly start from the anchor region in the first contact surface 38.

In one aspect, the growth direction, i.e. an axial or longitudinal direction of the nanowire 44 may at least partly depend on an crystal orientation in the first electrical contact 32, and particularly on a surface orientation of the semiconductor substrate 28. Substantially perpendicular growth on (111)-oriented silicon surfaces can be achieved. In another example, perpendicular growth may also be achieved on (001)-oriented silicon, for example. In one aspect, a native oxide may be removed from the first contact surface, i.e. with diluted HF. In one example, removal of the native oxide may be done prior to the catalyst deposition. In another example, the native oxide may be removed after the catalyst deposition.

In one aspect, an exemplary nanowire diameter d_{w} of about 5 nm to about 50 nm or about 10 nm to about 40 nm or about 10 nm to about 20 nm may be set by d_{c} as seen in FIG. 2D and it may have a sub-lithographic size. The length of the nanowire 44 can be set by the growth duration. In one example the nanowire length may be up to about 250 nm or even up to about 500 nm or even up to about 1 μm. Nevertheless, the nanowire is not limited to these lengths but also shorter or longer nanowires may be achieved or applied.

As shown in FIG. 2E, the nanowire 44 may be embedded in dielectric material or a dielectric separation layer 46 such as pre-metal dielectric layer. In the shown example of fabricating a nanowire via the dielectric material 46 may have a low effective dielectric constant K. In one example, the dielectric material 46 may be deposited on top of the lithographic hard mask 34. In this case the deposited dielectric material together with the lithographic hard mask 34 forms the dielectric separation layer 46. In another example the lithographic hard mask 34 may be removed before deposition of the dielectric material 46 on top of first process surface 30. As an exemplary dielectric material 46 spin-on glasses such as HSQTM (Dow Corning), TEOS or Si3N4 may be deposited by plasma enhanced-CVD, for example.

Subsequently, as shown in FIG. 2F, the dielectric separation layer 46 may be polished to provide a second process surface 48. In one example, chemical mechanical polishing (CMP) is applied for providing the second, exemplarily planar process surface 48. As shown in FIG. 2F, the second end portion of the nanowire 44 is uncovered by polishing the dielectric separation layer 46. This gives a top access to the nanowire 44 and may remove the catalyst seed 42.

In further processes, such as photolithography and etching for example, a second electrical contact may be fabricated at the second end portion of the nanowire 44. For example, as shown in FIG. 2G, a second circuit layer such as structure metallization layer may be fabricated on top of the second process surface 48 by depositing a dielectric trench isolation material or interconnect dielectric 50 at the second process surface 48 and lithographically forming a bit line groove or a trench 52 in the interconnect dielectric 50. This may uncover the second end portion of the nanowire 44. Subsequently, a metal reservoir 54 such as a Ni reservoir, for example, may be deposited at least at the second end portion of the nanowire 44 for an upcoming diffusion process. In one example, prior to the metal deposition, a treatment with HF may be performed in order to remove the native oxide on top of the nanowire 44. Deposition of the metal reservoir may be performed by e-beam evaporation or conformal by CVD, for example. Alternatively, metal such as Ni may be deposited on the uncovered end portion of the nanowire 44 by electro- or electroless-plating. In this example, Ni may be deposited where needed and the amount of Ni in the reservoir may be controlled. In case a wet metal deposition is used, the back-side of the integrated circuit or substrate may be previously coated with SiO₂ or Si₃N₄, for example, to prevent metal deposition on the back.

In one example, before re-oxidation of the nanowire, the sample may be annealed at a temperature between about 280° C. and about 480° C., for example. Annealing may be performed in an inert atmosphere such as argon (Ar), for example. In one aspect, a solid state reaction may take place in which the metal such as Ni diffuses from the metal reservoir or diffusion reservoir 54 axially along at least part of the nanowire 44. In one example it may diffuse along the entire length of the nanowire forming a nickel-silicide nanowire 44′, for example, as exemplarily shown in FIG. 2H. The nickel-silicide may have different phases such as NiSi, Ni₂Si, NiSi₂, for example. Accordingly, in one example, arranging the nanowire 44 comprises providing the nanowire 44 with semiconductor material, and the method further comprises enhancing the electrical conductance of the nanowire 44 by performing diffusion of metal atoms into the semiconductor material. In a further aspect, enhancing the electrical conductance of the nanowire 44 may comprise performing or achieving a solid state reaction between the semiconductor material and the diffused metal. Moreover, performing diffusion of metal atoms into the nanowire 44 may comprise depositing the metal reservoir 54 at least at the second end portion of the nanowire 44 and annealing the nanowire 44. In one aspect, the solid state reaction between the semiconductor material and the diffused metal may take place or be initiated through annealing of the nanowire 44. In one example, Ni may at least partly diffuse into the first electrical contact 32, which may comprise Si, doped Si or poly-Si, for example. This may also result in the formation of a silicide region in the first electrical contact and, therefore, may result in a reduction of the serial electrical resistance of the device.

In one example described in FIG. 2, enhancing the electrical conductance of the nanowire 44 is performed after embedding at least part of the nanowire 44 in the dielectric material 46. In another example described below, enhancing the electrical conductance of the nanowire 44 is performed after embedding at least part of the nanowire 44 in the dielectric material 46.

Depending on the Ni-silicide phase involved, the length and diameter of the transformed nanowire 44′ will increase up to 30%, for example. Most of the created strain may relax, since the nanowire can expand freely in the vertical direction in the shown in example. The remaining Ni can be removed selectively to Ni-silicide and SiO₂ by wet chemistry, i.e. with diluted HNO₃ in water, for example, as shown in FIG. 2J. In one example, another anneal step may follow after removal of the excess Ni. As shown in FIG. 2K, metal deposition and subsequent CMP may be applied to arrange a second electrical contact 56 at the second end portion of the nanowire 44′. The second electrical contact 56 may form at least part of a bit-line, for example.

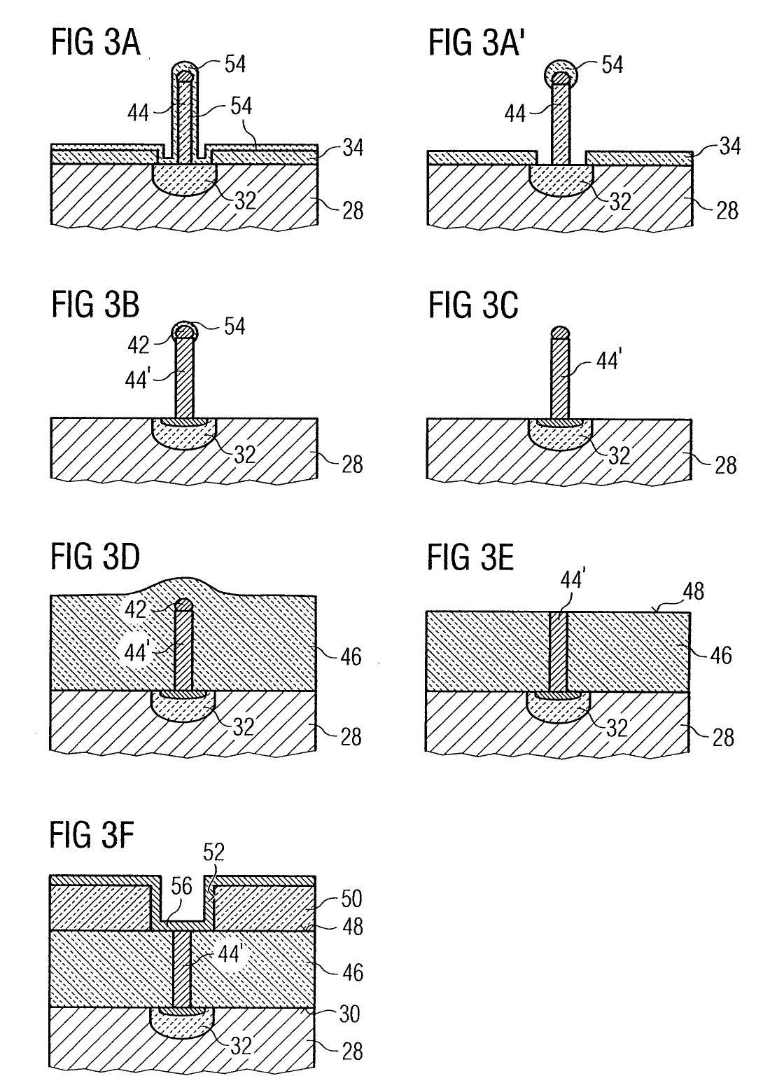

Another exemplary method of fabricating an integrated circuit is described in connection with FIG. 3, in the following. In this example, processes identical or similar to the processes exemplarily described in connection with FIGS. 2A to 2D, above, may be applied. In this example, a nanowire 44 grown on the first contact surface 38 as shown in FIG. 2D may be completely covered with diffusion material such as the diffusion reservoir or metal reservoir 54, as exemplarily shown in FIG. 3A. This may be done with conformal Ni CVD-deposition, for example. A Si-nanowire 44 without a surrounding native oxide may be achieved by a short HF dip before metallization, for example.

Alternatively, as shown in FIG. 3A′, starting from a nanowire 44 grown on the first contact surface 38 as shown in FIG. 1D, diffusion material or diffusion metal, such as Ni, for example, may be deposited as a diffusion reservoir or metal reservoir 54 at the second end portion of the nanowire 44 by electro- or electroless-deposition of Ni. This may allow to selectively deposit on the Au/Si eutectic (FIG. 3A′), while the nanowire 44 is covered with a native oxide.

For both examples shown in FIG. 3A and FIG. 3A′, annealing and the consequent nanowire silicidation is exemplarily shown in FIG. 3B, where in one aspect, diffusion may take place more rapidly in the example of FIG. 3A than in the example of FIG. 3A′. Annealing may be performed similar or analogous to the process described in connection with FIG. 2H, above. The excess Ni may be etched with wet chemistry as described above, for example (FIG. 3C).

Subsequently, similar to the processes described in connection with FIGS. 2E, 2F, above, the nanowire 44′ may be embedded in dielectric material or a dielectric separation layer 46 such as pre-metal dielectric layer, as shown in FIG. 3D. For further exemplary details it is referred to the respective description above.

As shown in FIG. 3E, the dielectric separation layer 46 may be polished to provide a second process surface 48, similar or analogous to the exemplary process describe in connection with FIG. 2F, above. Accordingly, for further exemplary details it is referred to the respective description.

In further processes, such as photolithography and etching for example, a second electrical contact 56 may be fabricated at the second end portion of the nanowire 44′, as exemplarily demonstrated in FIG. 3F. For example, analogous to FIG. 2G, above, with the difference that in FIG. 3F the nanowire 44′ is already silicided, a second circuit layer such as structured metallization layer may be fabricated on top of the second process surface 48 by depositing a dielectric trench isolation material or interconnect dielectric 50 at the second process surface 48 and lithographically forming a bit line groove or a trench 52 in the interconnect dielectric 50. This may uncover the second end portion of the nanowire 44′. Subsequently, as shown in FIG. 3F, metal deposition and subsequent CMP may be applied to arrange a second electrical contact 56 at the second end portion of the nanowire 44′. The second electrical contact 56 may form at least part of a lateral interconnection line, such as a bit-line, for example.

In one aspect of the examples described in connection with FIGS. 3A to 3F, no strain will be created during silicidation of the nanowire 44, since the dielectric deposition happens after the nanowire silicidation. In one aspect, diffusion of Ni in Si may be mostly interstitial and does not substantially change the unit cell of Si. When Ni reacts with Si to create silicide, the unit cell may change.

In the examples described above, the first electrical contact 32 may comprise at least partly crystalline material such as doped semiconductor material, for example. Arranging the nanowire 44 with its first end portion at the first contact surface 38 of the first electrical contact 32, therefore, may comprise arranging the nanowire 44 with its first end portion at the first contact surface of a first crystalline contact region comprised in the first electrical contact 32. Moreover, growing the nanowire 44 starting from the first contact surface 38 may comprise growing the nanowire having a crystalline structure with a crystal orientation in accordance with a crystal orientation of the crystalline contact region. In these examples the first circuit layer may comprise an at least partly crystalline substrate. In one aspect, it may comprise a substantially mono-crystalline substrate.

Accordingly, in one aspect, embedding at least part of the nanowire in dielectric material may comprise providing a pre-metal dielectric layer such that the nanowire extends through the pre-metal dielectric layer, and the method further comprises arranging a second contact region at the second end portion of the nanowire.

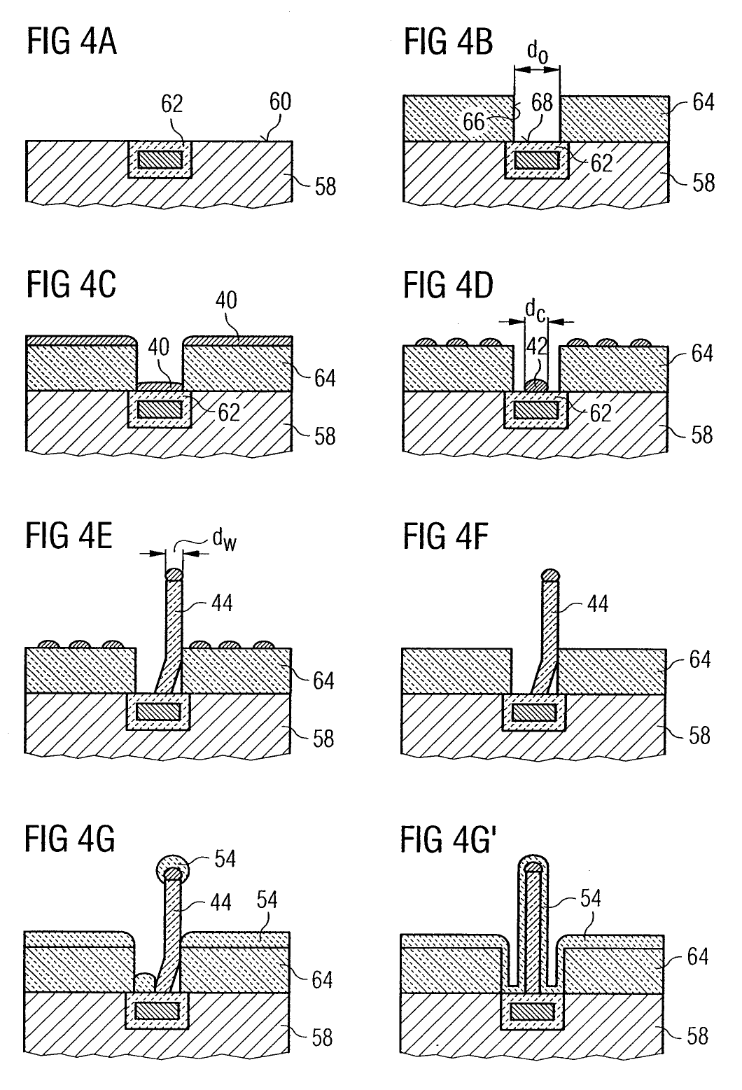

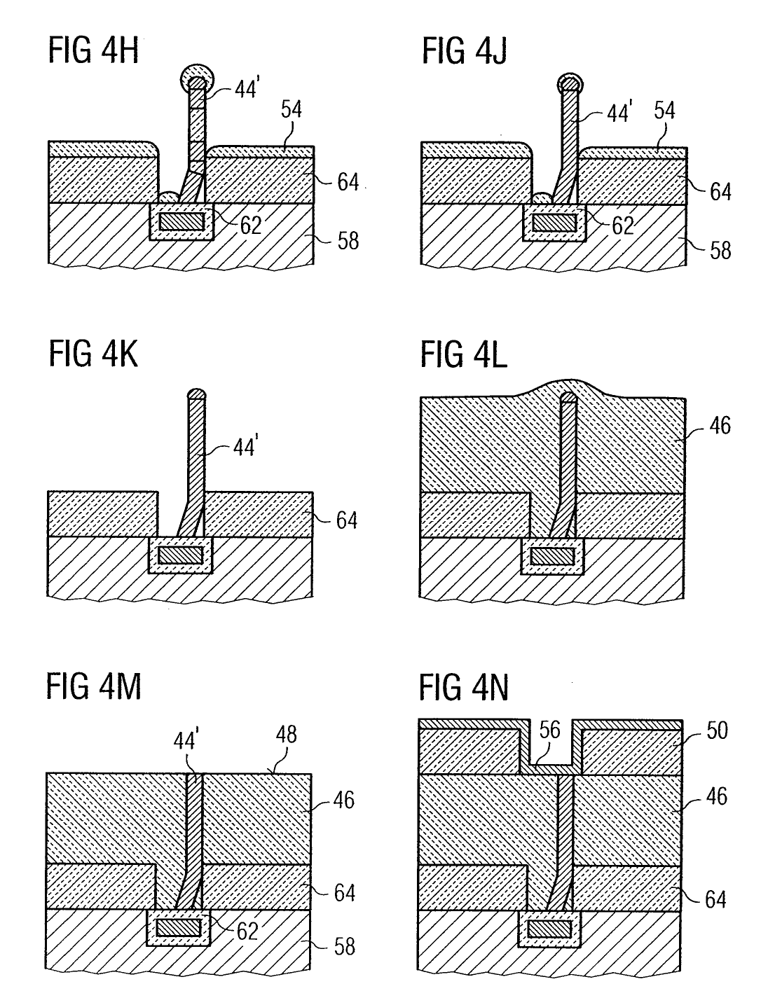

In another example of an integrated circuit and a method of fabricating an integrated circuit described in connection with FIGS. 4A to 4N in the following, a first circuit layer 58 such as a lateral interconnection layer or metallization layer as described in connection with FIG. 1, for example, may be provided with a first process surface 60. The first circuit layer 58 may be provided as a structured metallization layer comprising a first electrical contact 62 that may be provided as a lateral metallic interconnection line, as shown in FIG. 4A. In one example the first electrical contact 62 may comprise a diffusion barrier layer of TiN or TaN, for example, as shown in FIG. 4A. In one aspect, lateral metallic interconnect lines may be connected vertically with nanowire vias. An exemplary process of implementing a nanowire such as a nickel-silicide nanowire, for example, as high aspect ratio via is described.

As shown in FIG. 4B, a growth assistance layer 64 may be provided at the first process surface 60. The growth assistance layer 64 may comprise SiO₂, for example. In one example, the growth assistance layer may be provided with a thickness of about 150 nm, for example. In other examples, the growth assistance layer 64 may be provided with a layer thickness of between about 100 nm and about 5 μm, or between about 100 nm and about 2 μm, or between about 100 nm and about 750 nm, or between about 250 nm and about 750 nm, for example. In another example, the layer thickness may even be smaller than about 100 nm or it may be between about 100 nm and about 250 nm. As shown in FIG. 4B, the growth assistance layer 64 is provided with a growth guidance opening 66 to uncover a first contact surface 68 of the first electrical contact 62. The growth guidance opening may be provided with optical lithography and etching, for example.

A shown in FIGS. 4C and 4D, a catalyst layer 40 may be deposited as deposited and annealed to form a catalyst seed 42 at the first contact surface 68 as exemplarily described in connection with FIGS. 2C and 2D, above. Annealing in an inert atmosphere may support gold material exemplarily applied as a catalyst material to coalesce into one or many small droplets forming the at least one catalyst seed with a diameter d_{c} that may be substantially smaller than a diameter d₀ of the growth guidance opening. The diameter d_{c} may particularly depend on an amount of catalyst material deposited on the first contact surface 68, i.e. inside the growth guidance opening. The diffusion barrier layer, such as a TiN layer, of the first electric contact 62 may prevent the catalyst material from diffusion into the first electrical contact 68.

As shown in FIG. 4E, a growth of a nanowire 44, such as a silicon nanowire inside the growth guidance opening 66, also referred to as template hole, may take place in such a way, that a catalytic growth of a nanowire occurs only on the first contact surface 68 but not on the growth assistance layer. This may be achieved by selecting an appropriate growth temperature, for example. In one example, the growth temperature may be between about 320° C. and about 350° C. These exemplary temperatures may be used to selectively grow Si nanowires on the first electrical contact 62 (TiN, TaN, Si or poly-Si, for example) and not on the growth assistance layer 64 (SiO₂, for example).

In one aspect, the nanowire 44 may initially grow with a random growth direction, since the first electrical contact, and particularly, the first contact surface may comprise an amorphous structure. Nevertheless, when the nanowire gets in contact with the wall of the growth guidance opening, it may be forced to change growth direction. In the example shown in FIG. 4E, the nanowire 44 changes growth direction to a direction that is substantially perpendicular to the first contact surface 68 or substantially perpendicular to the first process surface 60. In one aspect, nanowire length may be substantially longer than the thickness of the growth assistance layer 64. The length of the nanowire 44 may be controlled by the processing conditions and the growth duration.

As shown in FIG. 4F, the unreacted catalyst material may be etched away selectively with wet chemistry, for example. Prior to a subsequent deposition of diffusion material 54 as shown in FIGS. 4G and 4G′, a native oxide covering the nanowire 44, such as a silicon nanowire, may be removed by wet etching using hydrofluoric acid (HF), for example. At least one diffusion reservoir 54, such as a Ni reservoir, may be located at either side of the nanowire. The diffusion reservoir may be deposited by various methods such vertical electron beam evaporation or sputtering (FIG. 4G), with a conformal process by CVD (FIG. 4G′) or by electro- and electroless plating methods, for example. Another quick HF-dip may ensure an unoxidized nanowire surface. Ni, TiN and the Si nanowires will not be affected and the SiO₂ hole-walls of the exemplary growth assistance layer 64 will only be negligibly etched.

Before re-oxidation of the nanowire, the sample may be annealed as described above. A solid state reaction may take place in which Ni diffuses along a part or the entire length of the Si-nanowire 44 forming a nickel-silicide nanowire, FIG. 4H, FIG. 4J. In one aspect, no strain is created during metal diffusion, since the nanowire can expand almost freely in the longitudinal and radial directions. The remaining Ni may be removed selectively with diluted HNO₃, for example, without affecting the TiN diffusion barrier layer, FIG. 4K.

Similar to the examples described above, in the example shown in FIGS. 4L to 4N, the nanowire 44 is covered with dielectric material 46 such as a low-κ dielectric. Deposition of the dielectric material may be performed with a spin on glass or with TEOS, for example. The deposited dielectric may form together with the growth assistance layer 64 a dielectric separation layer 46. Subsequently, CMP may be applied to planarize the dielectric separation layer 46 to provide a second process surface 48 and to uncover the second end portion of the nanowire 44, FIG. 4M. Further lithographic, etching and deposition processes may be applied as described above to arrange a second electrical contact at the second end portion of the nanowire 44, FIG. 4N. Accordingly, in this aspect the method may provide an integrated circuit with a nanowire via conductor for electrically connecting lateral interconnection lines within different metallization layer levels, for example.

Accordingly, in one aspect, the first circuit layer is provided as a first structured metallization layer, for example. Arranging the nanowire with its first end portion at the first contact surface of the first electrical contact region may comprise arranging the nanowire with its first end portion at the first contact surface of a non-crystalline first metal material region comprised in the first electrical contact region. Embedding at least part of the nanowire in dielectric material may comprise providing an inter-metal dielectric layer that comprises the growth assistance layer such that the nanowire extends through the inter-metal dielectric layer, and the method further comprises arranging a second contact region at the second end portion of the nanowire.

According to another aspect, growing the nanowire as an at least partly free standing nanowire may comprise providing a growth assistance layer with a growth guidance opening arranged at the first contact surface; and at least partly guiding the growth direction of the nanowire through the growth guidance opening in the growth assistance layer. In one example, a diameter d₀ of the growth guidance opening may be greater than a diameter d_{w} of the nanowire. In another example, not explicitly demonstrated above, the diameter d_{w} of the nanowire may be similar to the diameter d₀ of the growth guidance layer.

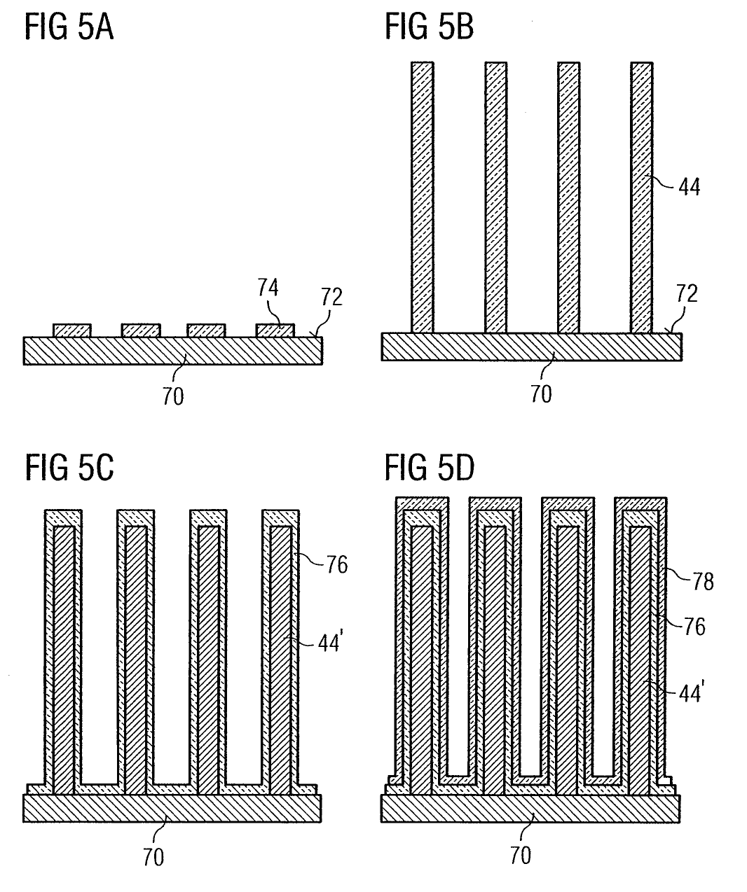

In yet another aspect, embedding at least part of the nanowire in dielectric material may comprise embedding at least part of the nanowire in a capacitor dielectric layer. The method may further comprise arranging at the capacitor dielectric layer a capacitor counter electrode. More exemplary details of an integrated circuit, a method of fabricating an integrated circuit and, particularly, a method of fabricating a capacitor structure in an integrated circuit according to this particular aspect are described in connection with FIGS. 5A to 5D, in the following.

As shown in FIG. 5A, a first electrical contact 70 may be provided with a first contact surface 72. At least one catalyst seed 74 may be arranged at the first contact surface 72 as describe above, for example. The catalyst seed may comprise one of the above described exemplary catalyst materials but it is not limited to the explicitly mentioned materials. The first electrical contact 70 may be formed as a doped semiconductor contact or as a metallic contact, as describe above, for example. The first electrical contact 70 may be deposited by sputtering, for example. The catalyst seed 74 may be provided at a predefined location or in a self-organized manner, for example.

As shown in FIG. 5B, at least one nanowire may be epitaxially grown in accordance with one of the above described examples. In particular a growth direction may be substantially perpendicular to the first contact surface 72. The nanowire 44 may be grown as a semiconductor nanowire and the electrical conductance of the nanowire may be enhanced by diffusion of metal atoms into the semiconductor nanowire. In particular, the nanowire 44 may be silicided.

As shown in FIG. 5C, the nanowire 44 may be at least partly embedded in a capacitor dielectric layer 76. The capacitor dielectric layer 76 may comprise Si₃N₄, AlSiO, HfSiO, Al₂O₃, HfO₂, Ta₂O₅ or ZrO₂, for example. In one example the capacitor dielectric layer 76 may be deposited by atomic layer deposition (ALD).

In a further aspect shown in FIG. 5D, a capacitor counter electrode 78 may be deposited at the capacitor dielectric layer 76. The capacitor counter electrode may comprise metal material such as TiN or TaN, for example. The capacitor counter electrode 78 may be deposited by chemical vapour deposition (CVD), for example.

As shown in FIGS. 5A to 5D, a plurality of nanowires 44 may be arranged at the first contact surface 72. In another example, each nanowire 44 may be arranged at a separate first electrical contact 70, i.e. each nanowire 44 may be contacted separately by individual electrical contacts. In one example, the capacitor structure may form storage capacitors of a DRAM device.

Accordingly, in one aspect, a method of fabricating a capacitor structure in an integrated circuit may comprise providing a first electrical contact with a first contact surface. The method may further comprise arranging at least one electrically conductive nanowire with a first end portion thereof at the first contact surface and with a second end portion sticking up from the first contact surface. Furthermore, the method may comprise at least partly embedding the nanowire in a capacitor dielectric layer and depositing at the capacitor dielectric layer a capacitor counter electrode.

In one example arranging at least one electrically conductive nanowire may comprise catalytically growing a semiconductor nanowire and diffusing metal atoms into the semiconductor nanowire. In a further example, arranging at least one electrically conductive nanowire may comprise performing or achieving a solid state reaction between the semiconductor nanowire and the diffused metal. In one particular example, this solid state reaction may be achieved simultaneous with the diffusion of the metal atoms. Moreover, in a further example, the first electrical contact may be provided as a source or drain contact of a field effect transistor of a memory device.

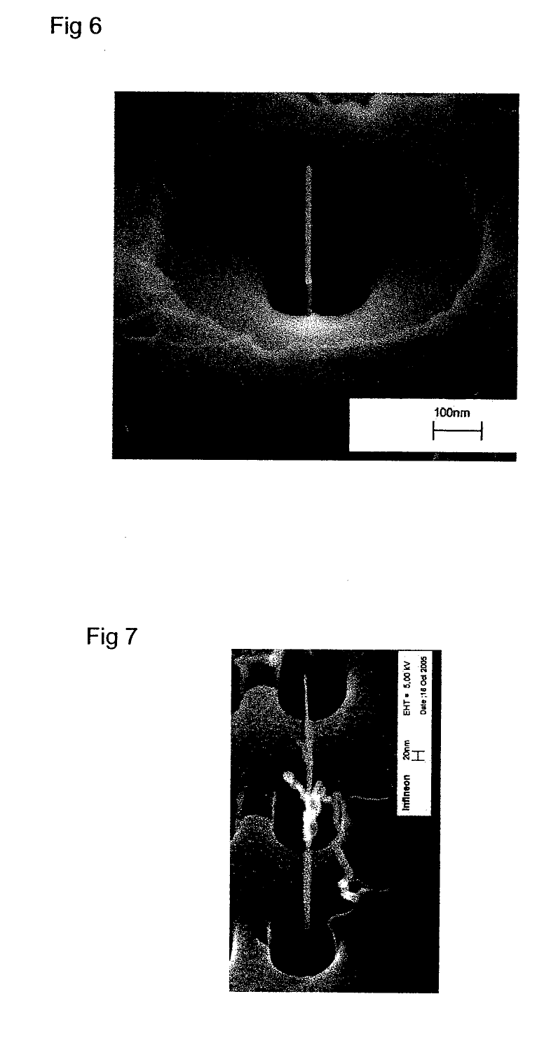

As shown in FIG. 6, single silicon nanowires may be grown out of lithographically defined holes with gold catalyst material. The nanowires demonstrated in FIG. 6 nucleate on a TaN layer at the bottom of the holes. Nevertheless, the nanowire, and particularly, silicon nanowires may be grown on different conductive or semiconducting substrates, such as TiN or n-type and p-type poly-Si, doped and undoped Si and undoped SiGe, for example. Silicon nanowires may also be grown out of very high aspects ratio holes, such as out of a DRAM trenches, as shown in FIG. 7.

In a further aspect, a silicon nanowire which is not single-crystalline may convert into a single-crystalline Ni-silicide nanowire, if the reaction is limited by the Ni content and the appropriate annealing conditions apply. This can be done by depositing the exact Ni amount needed to react or by letting react a part of the Ni content and subsequently etch the excess Ni away and continue with a second anneal.

A number of examples and implementations have been described. Other examples and implementations may, in particular, comprise one or more of the above features. Nevertheless, it will be understood that various modifications may be made. Particularly, an integrated circuit is not limited to a single nanowire arranged at a single first contact surface. In other example two or more nanowires or even a bundle of nanowires may be arrange at a single first contact surface of a first electrical contact. In one example, they may be arranged substantially in parallel to each other.

Moreover an alternative way of removing the catalyst metal on top of the growth assistance layer may be applied by covering the substrate of FIG. 4D with Si₃N₄ and to perform CMP to remove the undesired catalysts, for example. The remaining Si₃N₄ inside the template hole or growth guidance opening may be removed with wet chemistry (selective to SiO₂), uncovering the wanted catalyst inside the hole. With this modification, higher temperatures than 350° C. may be applied for the nanowire growth.

Depending on the applied catalyst material growth conditions and temperatures may be changed. Alternative to the explicitly shown examples the diffusion reservoir may be positioned at another part of the nanowire, for example at its top or at a side portion. There can be more than one diffusion reservoir at each nanowire.

Nanowires can also be oriented by an external force during growth, such as an electrical field, if an epitaxial relation of the substrate is missing. In such a way the nanowires may be oriented substantially vertically as shown in FIG. 4D or FIG. 4E, for example. Accordingly, growing the nanowire as an at least partly free standing nanowire may comprise growing the nanowire without epitaxial relation to the first electrical contact and guiding the growth direction by applying an external force such as an electrical field, for example. This may result in a substantially vertical growth, for example.

The integrated circuit is not limited to mono-crystalline nanowire vias. In other examples the nanowire may even contain Ni agglomerations. In yet another example, via holes may alternatively house an air-gap if a selective method is utilized to close the hole from above, without filling it completely. This may further reduce the effective dielectric constant between interconnects. Moreover, in another aspect, poly-Si or amorphous Si may be deposited in the via holes, for example by LPCVD and a damascene process, and to Ni-silicidize it completely. Furthermore, Ni-silicide nanowires may be applied as interconnects in other geometrical configurations, such as a horizontal one. In another aspect n- or p-doped Si-nanowires may be applied for an integrated circuit. Moreover, other silicidation like CoSi, TiSi, MoSi, PdSi, Wsi, HfSi, ZrSi, PtSi, TaSi, CrSi, AuSi, AgSi, or IrSi may be applied, for example. At least some or the silicides may have different phases.

Accordingly, other implementations are within the scope of the following claims.

What is claimed is:

1. A method of fabricating an integrated circuit, comprising:
arranging a nanowire with a first end portion thereof at a first contact surface of a first electrical contact and with a second end portion sticking up from the first contact surface; and
embedding at least part of the nanowire in dielectric material.

2. The method of claim 1, wherein arranging the nanowire comprises epitaxially growing the nanowire as an at least partly free standing nanowire starting the growth from the first contact surface.

3. The method of claim 1, wherein arranging the nanowire at the first electrical contact comprises
locally arranging a catalyst seed at an anchor region in the first contact surface; and
catalytically growing the nanowire starting from the anchor region.

4. The method of claim 3, wherein locally arranging a catalyst seed at the first contact surface comprises:
lithographically structuring a deposition mask to provide a catalyst deposition window at the first contact surface;
depositing catalyst material at the first contact surface as a catalyst layer within the deposition window; and
annealing the catalyst layer to form the catalyst seed at the anchor region in the first contact surface.

5. The method of claim 1, wherein arranging the nanowire comprises providing the nanowire with semiconductor material, and wherein the method further comprises enhancing the electrical conductance of the nanowire by performing diffusion of metal atoms into the semiconductor material.

6. The method of claim 5, wherein performing diffusion of metal atoms into the nanowire comprises:
depositing a metal reservoir at least at the second end portion of the nanowire; and
annealing the nanowire.

7. The method of claim 2, wherein arranging the nanowire with its first end portion at the first contact surface of the first electrical contact comprises arranging the nanowire with its first end portion at the first contact surface of a first crystalline contact region comprised in the first electrical contact, and wherein growing the nanowire starting from the first contact surface comprises growing the nanowire having a crystalline structure with a crystal orientation in accordance with a crystal orientation of the crystalline contact region.

8. The method of claim 2, wherein growing the nanowire as an at least partly free standing nanowire comprises:
providing a growth assistance layer with a growth guidance opening arranged at the first contact surface; and
at least partly guiding the growth direction of the nanowire through the growth guidance opening in the growth assistance layer.

9. The method of claim 2, wherein growing the nanowire as an at least partly free standing nanowire comprises:
growing the nanowire without epitaxial relation to the first electrical contact; and
guiding the growth direction by applying an external force.

10. A method of fabricating an electrical interlayer connection in an integrated circuit, the method comprising:
providing a first circuit layer with a first process surface, the first circuit layer comprising a first electrical contact;
arranging an electrically conductive nanowire with a first end portion thereof at the first electrical contact and with a second end portion sticking up from the process surface;
embedding the nanowire in a dielectric separation layer arranged at the first process surface and comprising a second process surface at least partly separated from the first process surface such that the nanowire extends through the dielectric separation layer from the first process surface to the second process surface; and
arranging a second electrical contact at the second process surface such that it electrically connects the nanowire.

11. The method of claim 10, wherein the first circuit layer is provided as an active semiconductor layer comprising transistor elements and wherein the first electrical contact is provided as a doped crystalline semiconductor region.

12. The method of claim 11, wherein the first electrical contact is provided as a source or drain contact of a semiconductor field effect transistor, and wherein the second electrical contact is provided as a bit line.

13. The method of claim 10, wherein the first electrical contact is provided as a gate contact of a field effect transistor, and wherein the second electrical contact is provided as a word line.

14. The method of claim 10, wherein the arranging the second electrical contact at the second process surface comprises arranging a second circuit layer comprising the second electrical contact.

15. The method of claim 14, wherein at least one of the first and second circuit layer is provided as a structured metallization layer and wherein at least one of the first and second electric contact is provided as a metal interconnection line.

16. The method of claim 10, wherein embedding the nanowire in a dielectric separation layer comprises:
depositing dielectric material on the first process surface to cover the nanowire; and
polishing the deposited dielectric material to provide the second process surface.

17. A method of fabricating a capacitor structure in an integrated circuit, the method comprising:
providing a first electrical contact with a first contact surface;
arranging at least one electrically conductive nanowire with a first end portion thereof at the first contact surface and with a second end portion sticking up from the first contact surface;
at least partly embedding the nanowire in a capacitor dielectric layer; and
depositing at the capacitor dielectric layer a capacitor counter electrode.

18. The method of claim 17, wherein arranging at least one electrically conductive nanowire comprises:
catalytically growing a semiconductor nanowire; and
diffusing metal atoms into the semiconductor nanowire.

19. The method of claim 18, wherein the first electrical contact is provided as a source or drain contact of a field effect transistor of a memory device.

20. An integrated circuit comprising:
a first circuit layer having at least one first electrical contact;
a second circuit layer separated from the first circuit layer and comprising at least one second electrical contact separated from the first electrical contact by a dielectric separation layer; and
a nanowire arranged in the dielectric separation layer and providing electrical conductance between the first electrical contact in the first circuit layer and the second electrical contact in the second circuit layer.

21. The integrated circuit of claim 20, wherein the nanowire is a doped semiconductor nanowire.

22. The integrated circuit of claim 20, wherein the nanowire comprises metal atoms.

23. The integrated circuit of claim 20, wherein the first circuit layer comprises a semiconductor operation layer and the first electrical contact comprises a source or drain or gate contact of a transistor.

24. The integrated circuit of claim 20, wherein at least one of the first and second circuit layer comprises a structured metallization layer and wherein at least one of the first and second electrical contact comprises a metal interconnection line.

25. The integrated circuit of claim 20, wherein the nanowire has a diameter of between 5 nm and 20 nm.

26. The integrated circuit of claim 20, wherein the nanowire comprises metal silicide material.

27. An integrate circuit comprising:
a first electrical contact arranged in a first circuit layer and having a first contact surface;
at least one electrically conductive nanowire arranged with a first end portion thereof at the first contact surface and with a second end portion sticking up from the first contact surface; and
a capacitor counter electrode separated from the at least one electrically conductive nanowire by a capacitor dielectric layer.

28. The integrated circuit of claim 27, wherein a major portion of the nanowire is embedded in the capacitor dielectric layer.

29. The integrated circuit of claim 27, wherein the first circuit layer comprises a select transistor of a memory cell and wherein the first electrical contact comprises a source or drain or gate contact of the select transistor.
